(19) United States
(12) Patent Application Publication
(10) Pub. No.: US 2012/0168735 A1
(43) Pub. Date: Jul. 5, 2012

(54) ORGANIC ELECTROLUMINESCENT DEVICE

(75) Inventors: Christof Pflumm, Frankfurt (DE); Frank Voges, Bad Duerkheim (DE)

(73) Assignee: Merck Patent GmbH, Darmstadt (DE)

(21) Appl. No.: 13/395,476

(22) PCT Filed: Aug. 16, 2010
(86) PCT No.: PCT/EP10/05022

§ 371 Date: Mar. 12, 2012

(30) Foreign Application Priority Data
Sep. 16, 2009 (DE) 10 2009 041 289.1

(51) Int. Cl. H01L 51/54; H01L 51/56

(52) U.S. Cl. 257/40; 438/34; 438/99; 257/E51.026

(57) ABSTRACT

The present invention relates to organic electroluminescent devices which comprise a thick electron-transport layer between the emitting layer and the cathode.

The present invention relates to organic electroluminescent devices which comprise thick electron-transport layers.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. A development in the area of organic electroluminescent devices is phosphorescent OLEDs. These have significant advantages compared with fluorescent OLEDs owing to the higher achievable efficiency.

However, there is still a need for improvement in the case of both fluorescent and phosphorescent OLEDs. Besides the efficiency and lifetime of the device, this also applies, in particular, to the colour coordinates and the emission spectrum and also to the production yield.

In order to achieve good colour purity, in particular in the case of green emission, use is made of complex technologies, such as top emission, in which a semi-transparent cathode and a reflective anode form a micro-cavity. This makes the emission spectrum narrower and thus improves the colour purity. However, top-emission OLEDs require process technology which is difficult to handle, for example the thicknesses of the different layers must be set very precisely.

Whereas top-emission OLEDs are more complex to achieve industrially due to the more complex structure, as described above, bottom-emission OLEDs have the problem that good colour coordinates are difficult to achieve. This relates, in particular, to the colour coordinates of the green emission layer, but also to the colour coordinates of the red or blue emission layer.

In order to improve the colour coordinates, it is in principle possible to employ coloured filters, but these have the disadvantage of resulting in reduced efficiency.

Improved colour coordinates can furthermore be achieved by employing materials having a narrower emission spectrum. However, there is still a considerable need for improvement in the case of materials of this type. In particular, phosphorescent materials having a narrow emission spectrum can at present not be achieved satisfactorily in industry. Thus, for example, the use of Ir(ppy)₃ (tris(phenylpyridine)iridium) in a bottom-emission OLED results in a CIE y coordinate of about 0.62, but a significantly higher CIE y coordinate, in particular a CIE y coordinate of about 0.71, would be desirable.

Furthermore, there continues to be a need for improvement in the yield in the mass production of OLEDs. The production of transparent OLEDs is likewise not possible in a simple manner, since the requisite TCOs (trans-parent conducting oxides) partially destroy the underlying organic layers of the OLED due to sputtering on application. Furthermore, improvements with respect to lifetime, efficiency and operating voltage are still desirable.

The technical object on which the present invention is based therefore consists in providing an organic electroluminescent device which has improved colour coordinates without the other properties of the electroluminescent device being impaired at the same time. This applies, in particular, to the lifetime, the efficiency and the operating voltage of the organic electroluminescent device. A further object consists in providing an organic electroluminescent device which has improved efficiency, which can be produced with a relatively high production yield and which is also suitable for the production of transparent electroluminescent devices.

In accordance with the prior art, an electron-transport layer having a layer thickness in the range from about 10 to 50 nm is generally used in organic electroluminescent devices. In the case of thicker electron-transport layers, a significant increase in the voltage and thus a significantly lower power efficiency is obtained.

Surprisingly, it has now been found that significant improvements are achieved and the above-mentioned technical object is achieved by the provision of an organic electroluminescent device which comprises an electron-transport layer having a layer thickness of at least 80 nm, where the material used in the electron-transport layer has an electron mobility of at least 10⁻⁵ cm²/Vs in a field of 10⁵V/cm.

The invention thus relates to an organic electroluminescent device comprising an anode, a cathode and at least one emitting layer, characterised in that an electron-transport layer which has a layer thickness of at least 80 nm and which has an electron mobility of at least 10⁻⁵ cm²/Vs in a field of 10⁵ V/cm is arranged between the emitting layer and the cathode.

The organic electroluminescent device according to the invention comprises the layers described above. The organic electroluminescent device need not necessarily comprise only layers which are built up from organic or organometallic materials. Thus, it is also possible for the anode, cathode and/or one or more layers to comprise inorganic materials or to be built up entirely from inorganic materials.

The electron mobility and the layer thickness of the electron-transport layer are determined as described in general terms below in the example part.

In a preferred embodiment of the invention, the layer thickness of the electron-transport layer is at least 100 nm, particularly preferably at least 120 nm, very particularly preferably at least 130 nm. The limits of 120 nm and 130 nm indicated here are particularly preferred for green- and red-emitting devices, whereas very good results are already achieved for blue-emitting devices having layer thicknesses of between 80 and 120 nm.

In a further preferred embodiment of the invention, the layer thickness of the electron-transport layer is not thicker than 500 nm, particularly preferably not thicker than 350 nm, in particular not thicker than 280 nm, for red-emitting OLEDs and not thicker than 250 nm for green-emitting OLEDs.

In a further preferred embodiment of the invention, the electron mobility of the electron-transport layer is at least 5×10⁻⁵ cm²/Vs in a field of 10⁵V/cm, particularly preferably at least 10⁻⁴ cm²/Vs in a field of 10⁵ V/cm.

The electron-transport layer here can consist of a pure material or it can consist of a mixture of two or more materials.

Furthermore, the electron-transport layer may have only one layer or it may be composed of a plurality of individual electron-transport layers whose total thickness is at least 80 nm and of which each individual layer has an electron mobility of at least 10⁻⁵ cm²/Vs in a field of 10⁵ V/cm.

In a preferred embodiment, the electron-transport layer comprises only organic or organometallic materials, where an organometallic compound in the sense of this application is taken to mean a compound which contains at least one metal atom or metal ion and at least one organic ligand. In a preferred embodiment of the invention, the electron-transport layer thus does not contain pure metals, i.e. is, for example, not doped with a metal, such as lithium.

In a further preferred embodiment of the invention, the electron-transport layer is not an n-doped layer, where n-doping is taken to mean that the electron-transport material is doped with an n-dopant and thus reduced. Although n-doping of this type results in high conductivity, it has, however, some clear disadvantages. Thus, the n-dopants are strong reducing agents, which are therefore highly sensitive to oxidation and have to be processed with particular care and under a protective gas. In industrial applications, such materials are difficult to handle. Furthermore, it is significantly more difficult to control the charge balance in the electroluminescent device with n-doped layers since the electron-transport layer has a large excess of electrons. In addition, n-doped layers frequently result in an impairment in the lifetime of the electroluminescent device.

In a further preferred embodiment of the invention, only materials which have an HOMO (highest occupied molecular orbital) of <−4 eV (i.e. with a numerical value of greater than 4 eV), particularly preferably <−4.5 eV, very particularly preferably <−5 eV, are used in the electron-transport layer. This excludes these materials being n-dopants, i.e. materials which release an electron to a further electron-transport material through a redox reaction.

In still a further preferred embodiment of the invention, only materials which have an (lowest unoccupied molecular orbital) of >−3.5 eV (i.e. with a numerical value of less than 3.5 eV), particularly preferably >−3 eV, are used in the electron-transport layer.

The materials which can be used for the electron-transport layer are not restricted further. In general, all electron-transport materials which satisfy the above-mentioned condition for electron mobility in the electron-trans-port layer are suitable.

Examples of suitable classes of electron-transport materials are selected from the structure classes of the triazine derivatives, the benzimidazole derivatives, the pyrimidine derivatives, the pyrazine derivatives, the pyridazine derivatives, the oxazole derivatives, the oxadiazole derivatives, the phenanthroline derivatives, the thiazole derivatives, the triazole derivatives or the aluminium, lithium or zirconium complexes. In each of these structure classes, it should be determined, depending on the precise structure and composition of the layer, whether these materials have the electron mobility according to the invention in the electron-transport layer or not. It is not possible to predict the electron mobility, but instead the electron mobility must be determined empirically for each material in the respective layer. The electron mobility is dependent both on the precise composition of the layer and on the production. Thus, for example, different vapour-deposition rates during production by sublimation result in different electron mobilities. Different electron mobilities again are obtained if the layer is produced from solution.

Examples of suitable electron-transport materials are revealed by the experimental examples in this application.

The electron-transport materials can also be employed in combination with an organic alkali-metal compound in the electron-transport layer, in which case the mixed layer must satisfy the above-mentioned condition for electron mobility. “In combination with an organic alkali-metal compound” here means that the triazine derivative and the alkali-metal compound are either in the form of a mixture in one layer or are present separately in two successive layers.

An organic alkali-metal compound in the sense of this invention is intended to be taken to mean a compound which contains at least one alkali metal, i.e. lithium, sodium, potassium, rubidium or caesium, and which furthermore contains at least one organic ligand.

Suitable organic alkali-metal compounds are, for example, the compounds disclosed in WO 2007/050301, WO 2007/050334 and EP 1144543. These are incorporated into the present application by way of reference.

Preferred organic alkali-metal compounds are the compounds of the following formula (1):

where R¹ has the same meaning as described below for the formulae (5) to (8), the curved line represents two or three atoms and bonds which are necessary to make up a 5- or 6-membered ring with M, where these atoms may also be substituted by one or more radicals R¹, and M represents an alkali metal selected from lithium, sodium, potassium, rubidium or caesium.

It is possible here for the complex of the formula (1) to be in monomeric form, as depicted above, or to be in the form of aggregates, for example comprising two alkali-metal ions and two ligands, four alkali-metal ions and four ligands, six alkali-metal ions and six ligands, or other aggregates.

Preferred compounds of the formula (1) are the compounds of the following formulae (2) and (3):

where the symbols used have the same meaning as described below for the formulae (5) to (8) and above for the formula (1), and m stands, identically or differently on each occurrence, for 0, 1, 2 or 3, and o stands, identically or differently on each occurrence, for 0, 1, 2, 3 or 4.

Further preferred organic alkali-metal compounds are the compounds of the following formula (4):

where the symbols used have the same meaning as described below for the formulae (5) to (8) and above for the formula (1).

The alkali metal is preferably selected from lithium, sodium and potassium, particularly preferably lithium and sodium, very particularly preferably lithium.

Particular preference is given to a compound of the formula (2), in particular where M=lithium. Furthermore, the indices m are very particularly preferably=0. The compound is thus very particularly preferably unsubstituted lithium quinolinate.

Examples of suitable organic alkali-metal compounds are structures (1) to (45) shown in the following table.

| | |
|---|---|
| | (1) |
| | (2) |
| | (3) |
| | (4) |
| | (5) |
| | (6) |
| | (7) |
| | (8) |
| | (9) |
| | (10) |
| | (11) |
| | (12) |
| | (13) |
| | (14) |
| | (15) |
| | (16) |
| | (17) |
| | (18) |
| | (19) |
| | (20) |
| | (21) |
| | (22) |
| | (23) |
| | (24) |
| | (25) |
| | (26) |
| | (27) |
| | (28) |
| | (29) |
| | (30) |
| | (31) |
| | (32) |
| | (33) |
| | (34) |
| | (35) |
| | (36) |
| | (37) |
| | (38) |
| | (39) |
| | (40) |
| | (41) |
| | (42) |
| | (43) |
| | (44) |
| | (45) |

In a preferred embodiment of the invention, only one material and not a mixture of materials is employed in the electron-transport layer according to the invention. It is thus preferably a pure layer.

Apart from the cathode, the anode, the emitting layer and the electron-transport layer according to the invention, which has been described above, the organic electroluminescent device may also comprise further layers. These are selected, for example, from in each case one or more hole-injection layers, hole-transport layers, hole-blocking layers, electron-transport layers, electron-injection layers, electron-blocking layers, exciton-blocking layers, charge-generation layers and/or organic or inorganic p/n junctions. In addition, interlayers which control, for example, the charge balance in the device may be present. In particular, such interlayers may be appropriate as interlayer between two emitting layers, in particular as interlayer between a fluorescent layer and a phosphorescent layer. Furthermore, the layers, in particular the charge-transport layers, may also be doped. However, it should be pointed out that each of the layers mentioned above does not necessarily have to be present, and the choice of layers is always dependent on the compounds used. The use of layers of this type is known to the person skilled in the art, and he will be able to use all materials in accordance with the prior art that are known for such layers for this purpose without inventive step.

It is furthermore possible to use more than one emitting layer, for example two or three emitting layers, which preferably emit different emission colours. A particularly preferred embodiment of the invention relates to a white-emitting organic electroluminescent device. This is characterised in that it emits light having CIE colour coordinates in the range from 0.28/0.29 to 0.45/0.41. The general structure of a white-emitting electroluminescent device of this type is disclosed, for example, in WO 2005/011013.

The organic electroluminescent device according to the invention may be a top-emission OLED or a bottom-emission OLED. In a preferred embodiment of the invention, it is a bottom-emission OLED, since the effect according to the invention of improved colour coordinates becomes particularly clear here. In a top-emission OLED, the influence of the device structure according to the invention on the colour coordinates is less pronounced, but the other advantages mentioned of the device structure according to the invention are also achieved in a top-emission OLED.

The cathode of the electroluminescent device according to the invention preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). In the case of multilayered structures, further metals which have a relatively high work function, such as, for example, Ag, may also be used in addition to the said metals, in which case combinations of the metals, such as, for example, Ca/Ag, Mg/Ag or Ba/Ag, are generally used. Preference is likewise given to metal alloys, in particular alloys comprising an alkali metal or alkaline-earth metal and silver, particularly preferably an alloy of Mg and Ag. It may also be preferred to introduce a thin interlayer of a material having a high dielectric constant as electron-injection layer between a metallic cathode and the organic semiconductor, in particular between a metallic cathode and the electron-transport layer according to the invention. Suitable for this purpose are, for example, alkali metal or alkaline-earth metal fluorides, but also the corresponding oxides or carbonates (for example LiF, Li₂O, CsF, Cs₂CO₃, BaF₂, MgO, NaF, etc.). Also suitable for this purpose are alkali metal or alkaline-earth metal complexes, such as, for example, Liq (lithium quinolinate) or the other compounds mentioned above. The layer thickness of an electron-injection layer of this type is preferably between 0.5 and 5 nm. For the coupling of light out of the cathode (top emission), it is preferred for the cathode to have a transmission of >20% at a wavelength of 500 nm. A preferred cathode material for top emission is an alloy of magnesium and silver.

The anode of the electroluminescent device according to the invention preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. The anode material used for a top-emission OLED is preferably a reflective layer in combination with ITO, for example silver+ITO. At least one of the electrodes here must be transparent or partially transparent in order to facilitate the coupling-out of light. A preferred structure uses a transparent anode (bottom emission). Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

The device is correspondingly (depending on the application) structured, provided with contacts and finally hermetically sealed, since the lifetime of devices of this type is drastically shortened in the presence of water and/or air.

In general, all further materials as employed in accordance with the prior art in organic electroluminescent devices can be employed in combination with the electron-transport layer according to the invention.

The emitting layer (or the emitting layers if a plurality of emitting layers are present) can be fluorescent or phosphorescent and can have any desired emission colour. In a preferred embodiment of the invention, the emission layer (or emission layers) is a red-, green-, blue- or white-emitting layer.

A red-emitting layer is taken to mean a layer whose photoluminescence maximum is in the range from 570 to 750 nm. A green-emitting layer is taken to mean a layer whose photoluminescence maximum is in the range from 490 to 570 nm. A blue-emitting layer is taken to mean a layer whose photoluminescence maximum is in the range from 440 to 490 nm. The photoluminescence maximum here is determined by measurement of the photoluminescence spectrum of the layer having a layer thickness of 50 nm.

In a preferred embodiment of the invention, the emitting layer is a green-emitting layer. This preference is due to the fact that a particularly strong influence of the electron-transport layer on the colour coordinates is observed here and that it is particularly difficult, in particular for green emission, to optimise the colour coordinates by modification of the device structure. It is also technically virtually impossible at present to achieve the desired colour coordinates through the choice of the green emitter, in particular if it is a phosphorescent emitter.

In a preferred embodiment of the invention, the emitting compound in the emitting layer is a phosphorescent compound.

A phosphorescent compound in the sense of this invention is a compound which exhibits luminescence from an excited state of relatively high spin multiplicity, i.e. a spin state >1, in particular from an excited triplet state, at room temperature. For the purposes of this invention, all luminescent transition-metal complexes containing transition metals from the second and third transition-metal series, in particular all luminescent iridium, platinum and copper compounds, are to be regarded as phosphorescent compounds.

In a preferred embodiment of the invention, the phosphorescent compound is a red-phosphorescent compound or a green-phosphorescent compound, in particular a green-phosphorescent compound.

Suitable phosphorescent compounds are, in particular, compounds which emit light, preferably in the visible region, on suitable excitation and in addition contain at least one atom having an atomic number of greater than 20, preferably greater than 38 and less than 84, particularly preferably greater than 56 and less than 80. The phosphorescence emitters used are preferably compounds which contain copper, molybdenum, tungsten, rhenium, ruthenium, osmium, rhodium, iridium, palladium, platinum, silver, gold or europium, in particular compounds which contain iridium, platinum or copper.

Particularly preferred organic electroluminescent devices comprise, as phosphorescent compound, at least one compound of the formulae (5) to (8):

where the following applies to the symbols used:
DCy is, identically or differently on each occurrence, a cyclic group which contains at least one donor atom, preferably nitrogen, carbon in the form of a carbene or phosphorus, via which the cyclic group is bonded to the metal, and which may in turn carry one or more substituents R¹; the groups DCy and CCy are bonded to one another via a covalent bond;
CCy is, identically or differently on each occurrence, a cyclic group which contains a carbon atom via which the cyclic group is bonded to the metal and which may in turn carry one or more substituents R¹;
A is, identically or differently on each occurrence, a monoanionic, bidentate chelating ligand, preferably a diketonate ligand;
R¹ is on each occurrence, identically or differently, H, D, F, Cl, Br, I, CHO, C(═O)Ar¹, P(═O)(Ar¹)₂, S(═O)Ar¹, S(═O)₂Ar¹, CR²═CR²Ar¹, CN, NO₂, Si(R²)₃, B(OR²)₂, B(R²)₂, B(N(R²)₂)₂, OSO₂R², a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which may be substituted by one or more radicals R², where one or more non-adjacent CH₂ groups may be replaced by R²C═CR², G≡C, Si(R²)₂, Ge(R²)₂, Sn(R²)₂, C═O, C═S, C═Se, C═NR², P(═O)(R²), SO, SO₂, NR², O, S or CONR² and where one or more H atoms may be replaced by F, Cl, Br, I, CN or NO₂, or an aromatic or heteroaromatic ring system having 5 to 60 aromatic ring atoms, which may in each case be substituted by one or more radicals R², or an aryloxy or heteroaryloxy group having 5 to 60 aromatic ring atoms, which may be substituted by one or more radicals R², or a combination of these systems; two or more adjacent substituents R¹ here may also form a mono- or polycyclic, aliphatic or aromatic ring system with one another;
Ar¹ is on each occurrence, identically or differently, an aromatic or heteroaromatic ring system having 5 to 40 aromatic ring atoms, which may be substituted by one or more radicals R²;
R² is on each occurrence, identically or differently, H, D, CN or an aliphatic, aromatic and/or heteroaromatic hydrocarbon radical having 1 to 20 C atoms, in which, in addition, H atoms may be replaced by F; two or more adjacent substituents R² here may also form a mono- or polycyclic, aliphatic or aromatic ring system with one another.

Due to formation of ring systems between a plurality of radicals R¹, a bridge may also be present between the groups DCy and CCy. Furthermore, due to formation of ring systems between a plurality of radicals R¹, a bridge may also be present between two or three ligands CCy-DCy or between one or two ligands CCy-DCy and the ligand A, giving a polydentate or polypodal ligand system.

Examples of the emitters described above are revealed by the applications WO 2000/70655, WO 2001/41512, WO 2002/02714, WO 2002/15645, EP 1191613, EP 1191612, EP 1191614, WO 2004/081017, WO 2005/033244, WO 2005/042550, WO 2005/113563, WO 2006/008069, WO 2006/061182, WO 2006/081973, WO 2009/118087, WO 2009/146770 and the unpublished application DE 102009007038.9. In general, all phosphorescent complexes as used in accordance with the prior art for phosphorescent OLEDs and as are known to the person skilled in the art in the area of organic electroluminescence are suitable, and the person skilled in the art will be able to use further phosphorescent compounds without inventive step. In particular, the person skilled in the art knows which phosphorescent complexes emit with which emission colour.

Suitable matrix materials for the compounds according to the invention are ketones, phosphine oxides, sulfoxides and sulfones, for example in accordance with WO 2004/013080, WO 2004/093207, WO 2006/005627 or WO 2010/006680, triarylamines, carbazole derivatives, for example CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example in accordance with WO 2007/063754 or WO 2008/056746, indenocarbazole derivatives, for example in accordance with the unpublished applications DE 102009023155.2 and DE 102009031021.5, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, diazasilole derivatives, for example in accordance with WO 2010/054729, diazaphosphole derivatives, for example in accordance with WO 2010/054730, triazine derivatives, for example in accordance with WO 2010/015306, WO 2007/063754 or WO 2008/056746, zinc complexes, for example in accordance with EP 652273 or WO 2009/062578, dibenzofuran derivatives, for example in accordance with WO 2009/148015, or bridged carbazole derivatives, for example in accordance with US 2009/0136779, WO 2010/050778 or the unpublished applications DE 102009048791.3 and DE 102010005697.9.

It may also be preferred to employ a plurality of different matrix materials as a mixture, in particular at least one electron-conducting matrix material and at least one hole-conducting matrix material. A preferred combination is, for example, the use of an aromatic ketone or a triazine derivative with a triarylamine derivative or a carbazole derivative as mixed matrix for the metal complex according to the invention. Preference is likewise given to the use of a mixture of a charge-transporting matrix material and an electrically inert matrix material which is not or not significantly involved in charge transport, as described, for example, in the unpublished application DE 102009014513.3.

In a further preferred embodiment of the invention, the organic electroluminescent device, in particular in the case of the use of a phosphorescent emission layer, comprises a hole-blocking layer between the emission layer and the electron-transport layer according to the invention.

In a further preferred embodiment of the invention, the emitting layer is a fluorescent layer, in particular a blue- or green-fluorescent layer.

Preferred dopants which can be employed in the fluorescent emitter layer are selected from the class of the monostyrylamines, the distyrylamines, the tristyrylamines, the tetrastyrylamines, the styrylphosphines, the styryl ethers and the arylamines. A monostyrylamine is taken to mean a compound which contains one substituted or unsubstituted styryl group and at least one, preferably aromatic, amine. A distyrylamine is taken to mean a compound which contains two substituted or unsubstituted styryl groups and at least one, preferably aromatic, amine. A tristyrylamine is taken to mean a compound which contains three substituted or unsubstituted styryl groups and at least one, preferably aromatic, amine. A tetrastyrylamine is taken to mean a compound which contains four substituted or unsubstituted styryl groups and at least one, preferably aromatic, amine. The styryl groups are particularly preferably stilbenes, which may also be further substituted. Corresponding phosphines and ethers are defined analogously to the amines. For the purposes of this invention, an arylamine or aromatic amine is taken to mean a compound which contains three substituted or unsubstituted aromatic or heteroaromatic ring systems bonded directly to the nitrogen. At least one of these aromatic or heteroaromatic ring systems is preferably a condensed ring system, particularly preferably having at least 14 aromatic ring atoms. Preferred examples thereof are aromatic anthracenamines, aromatic anthracenediamines, aromatic pyrenamines, aromatic pyrenediamines, aromatic chrysenamines or aromatic chrysenediamines. An aromatic anthracenamine is taken to mean a compound in which a diarylamino group is bonded directly to an anthracene group, preferably in the 2- or 9-position. An aromatic anthracenediamine is taken to mean a compound in which two diarylamino groups are bonded directly to an anthracene group, preferably in the 2,6- or 9,10-position. Aromatic pyrenamines, pyrenediamines, chrysenamines and chrysenediamines are defined analogously thereto, where the diarylamino groups on the pyrene are preferably bonded in the 1-position or in the 1,6-position. Further preferred fluorescent dopants are selected from indenofluorenamines or indenofluorenediamines, for example in accordance with WO 2006/122630, benzoindenofluorenamines or benzoindenofluorene-diamines, for example in accordance with WO 2008/006449, and dibenzoindenofluorenamines or dibenzoindenofluorenediamines, for example in accordance with WO 2007/140847. Examples of dopants from the class of the styrylamines are substituted or unsubstituted tristilbenamines or the dopants described in WO 2006/000388, WO 2006/058737, WO 2006/000389, WO 2007/065549 and WO 2007/115610. Fluorescent dopants which are furthermore preferred are condensed aromatic hydrocarbons, such as, for example, the compounds disclosed in WO 2010/012328. Particularly preferred fluorescent dopants are aromatic amines which contain at least one condensed aromatic group having at least 14 aromatic ring atoms, and condensed aromatic hydrocarbons.

In a further preferred embodiment of the invention, the host material of the fluorescent layer is an electron-transporting material. This preferably has an LUMO (lowest unoccupied molecular orbital) of <−2.3 eV, particularly preferably <−2.5 eV. The LUMO is determined here as described in general terms below in the example part.

Suitable host materials (matrix materials) for the fluorescent dopants, in particular for the above-mentioned dopants, are selected, for example, from the classes of the oligoarylenes (for example 2, 2′,7,7′-tetraphenyl-spirobifluorene in accordance with EP 676461 or dinaphthylanthracene), in particular the oligoarylenes containing condensed aromatic groups, the oligoarylenevinylenes (for example DPVBi or spiro-DPVBi in accordance with EP 676461), the polypodal metal complexes (for example in accordance with WO 2004/081017), the electron-conducting compounds, in particular ketones, phosphine oxides, sulfoxides, etc. (for example in accordance with WO 2005/084081 and WO 2005/084082), the atropisomers (for example in accordance with WO 2006/048268), the boronic acid derivatives (for example in accordance with WO 2006/117052), the benzanthracene derivatives (for example benz[a]anthracene derivatives in accordance with WO 2008/145239 or in accordance with the unpublished application DE 102009034625.2) and the benzophenanthrene derivatives (for example benzo[c]phenanthrene derivatives in accordance with the unpublished application DE 102009005746.3). Particularly preferred host materials are selected from the classes of the oligoarylenes, containing naphthalene, anthracene, benzanthracene, in particular benz[a]anthracene, benzophenanthrene, in particular benzo[c]phenanthrene, and/or pyrene, or atropisomers of these compounds. For the purposes of this invention, an oligoarylene is intended to be taken to mean a compound in which at least three aryl or arylene groups are bonded to one another.

Particularly preferred host materials are compounds of the following formula (9):

Ar²-Ant-Ar² formula (9)

where R¹ has the meaning indicated above, and the following applies to the other symbols used:
Ant stands for an anthracene group which is substituted by the groups Ar² in the 9- and 10-position and which may furthermore be substituted by one or more substituents R¹;
Ar² is, identically or differently on each occurrence, an aromatic or heteroaromatic ring system having 5 to 60 aromatic ring atoms, which may be substituted by one or more radicals R¹.

In a preferred embodiment of the invention, at least one of the groups Ar² contains a condensed aryl group having 10 or more aromatic ring atoms, where Ar² may be substituted by one or more radicals R¹. Preferred groups Ar² are selected, identically or differently on each occurrence, from the group consisting of phenyl, 1-naphthyl, 2-naphthyl, anthracenyl, ortho-, meta- or para-biphenyl, phenylene-1-naphthyl, phenylene-2-naphthyl, phenanthrenyl, benz[a]anthracenyl or benzo[c]phenanthrenyl, each of which may be substituted by one or more radicals R¹.

Suitable hole-transport materials, as can be used in the hole-injection or hole-transport layer or in the electron-transport layer of the organic electroluminescent device according to the invention, are, for example, the compounds disclosed in Y. Shirota et al., Chem. Rev. 2007, 107(4), 953-1010, or other materials as employed in accordance with the prior art in these layers.

Examples of preferred hole-transport materials which can be used in a hole-transport or hole-injection layer in the electroluminescent device according to the invention are indenofluorenamines and derivatives (for example in accordance with WO 2006/122630 or WO 2006/100896), the amine derivatives disclosed in EP 1661888, hexaazatriphenylene derivatives (for example in accordance with WO 2001/049806), amine derivatives containing condensed aromatic ring systems (for example in accordance with U.S. Pat. No. 5,061,569), the amine derivatives disclosed in WO 95/09147, monobenzoindenofluorenamines (for example in accordance with WO 2008/006449), dibenzoindenofluorenamines (for example in accordance with WO 2007/140847) or piperidine derivatives (for example in accordance with the unpublished application DE 102009005290.9). Hole-transport and hole-injection materials which are furthermore suitable are derivatives of the compounds depicted above, as disclosed in JP 2001/226331, EP 676461, EP 650955, WO 2001/049806, U.S. Pat. No. 4,780,536, WO 98/30071, EP 891121, EP 1661888, JP 2006/253445, EP 650955, WO 2006/073054 and U.S. Pat. No. 5,061,569.

Suitable hole-transport or hole-injection materials are furthermore, for example, the materials listed in the following table.

| | |
|---|---|
| | |
| | |
| | |
| | |
| | |
| | |
| | |
| | |
| | |
| | |

Preference is furthermore given to an organic electroluminescent device, characterised in that one or more layers are applied by means of a sublimation process, in which the materials are vapour-deposited in vacuum sublimation units at an initial pressure of less than 10⁻⁵ mbar, preferably less than 10⁻⁶ mbar. However, it should be noted that the initial pressure may also be even lower, for example less than 10⁻⁷ mbar.

Preference is likewise given to an organic electroluminescent device, characterised in that one or more layers are applied by means of the OVPD (organic vapour phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing, LITI (light induced thermal imaging, thermal transfer printing), inkjet printing or nozzle printing. Soluble compounds are necessary for this purpose. High solubility can be achieved through suitable substitution of the compounds. It is possible here not only for solutions of individual materials to be applied, but also solutions which comprise a plurality of compounds, for example matrix materials and dopants.

The present invention therefore furthermore also relates to a process for the production of an electroluminescent device according to the invention, characterised in that at least one layer is applied by means of a sublimation process or by means of the OVPD (organic vapour phase deposition) process or with the aid of carrier-gas sublimation or from solution, such as, for example, by spin coating, or by means of any desired printing process.

The organic electroluminescent device can also be produced as a hybrid system by applying one or more layers from solution and applying one or more further layers by vapour deposition. Thus, for example, the emitting layer can be applied from solution and the electron-transport layer according to the invention can be applied to this layer by vapour deposition.

These processes are generally known to the person skilled in the art and can be applied by him without inventive step to the organic electroluminescent devices according to the invention.

The organic electroluminescent devices according to the invention have the following surprising advantages over the prior art:
1. The organic electroluminescent device according to the invention has very high efficiency. The efficiency here is better than in the case of the use of a thinner electron-transport layer.
2. The organic electroluminescent device according to the invention has significantly improved colour coordinates. This applies, in particular, to green-emitting electroluminescent devices.
3. In spite of the significantly thicker electron-transport layer compared with the prior art, the organic electroluminescent device according to the invention has virtually unchanged or only minimally higher operating voltages, meaning that the power efficiency of the electroluminescent device is nevertheless improved compared with the prior art.
4. The organic electroluminescent device according to the invention enables the production of transparent OLEDs, since the requisite transparent conductive oxides which are used as electrodes can be applied to the thick electron-transport layer by sputtering without destroying the latter.
5. The organic electroluminescent device according to the invention can be produced with an improved production yield since it produces fewer short circuits due to the thicker layers.
6. The lifetime of the organic electroluminescent device according to the invention is comparable with or better than that of an organic electroluminescent device in accordance with the prior art comprising a thinner electron-transport layer.

The invention is described in greater detail by the following examples without wishing to restrict it thereby. The person skilled in the art will be able to produce further organic electroluminescent devices according to the invention without inventive step.

### EXAMPLES

### General Determination of the Electron Mobility

The electron mobility in the sense of the present invention is determined by the general method described below:

The electron mobility is determined using the “time of flight” (TOF) method frequently employed for this purpose, in which charge carriers are generated in a single-layer component of the material to be investigated with the aid of a laser pulse. These are separated by an applied field. The holes leave the component, whereas the electrons move through the layer and thus cause a current flow. The transit time of the electrons and thus the mobility can be determined from the variation in the current over time.

The material to be investigated is applied to glass plates coated with structured ITO in a thickness of 150 nm at a vapour-deposition rate of 0.3 nm/s in a layer thickness of 2 μm. An aluminium layer with a thickness of 100 nm is deposited on top. The components formed have an area of 2 mm×2 mm. The component is irradiated using an N2 laser (wavelength 337 nm, pulse duration 4 ns, pulse frequency 10 Hz, pulse energy 100 μJ) through the ITO layer. The field strength of the applied field E is 10⁵ V/cm. The variation in the photocurrent over time is recorded using an oscilloscope. In a double-logarithmic plot of the current as a function of time, two linear sections are obtained whose intersection is used as the transit time t. The mobility μ arises therefrom and with the applied field E and the layer thickness d as μ=d/(t*E) or with the applied field E=10⁵ V/cm and the layer thickness d=2 μm as μₑ=2 μm/(t*10⁵ V/cm). A more detailed description of the method is given, for example, in Redecker et al., Applied Physics Letters, Vol. 173, p. 1565.

### General Determination of the Layer Thickness

The layer thickness in the sense of the present invention is determined by the general method described below:

Since the thicknesses of the individual layers cannot be measured directly on the OLEDs produced, they are monitored during vapour deposition, as generally usual, with the aid of a quartz resonator. To this end, the vapour deposition rate is required, which is somewhat different from material to material, which is why a calibration of the vapour-deposition rate is carried out before the production of the OLEDs. If the vapour-deposition rate is known, any desired layer thickness can be set over the duration of the vapour-deposition process.

In order to calibrate the vapour-deposition rate, a “test layer” of the material to be vapour-deposited is applied to a glass substrate, and the (as yet uncalibrated) vapour-deposition rate is recorded during the vapour deposition. The vapour-deposition duration here is selected with reference to experience values in such a way that a layer with a thickness of about 100 nm is obtained. The thickness of the test layer is then determined with the aid of a profilometer (see below). The layer thickness now known can be used to determine a corrected vapour-deposition rate, which is used in the further production of the OLEDs.

The thickness of the test layer is determined with the aid of a profilometer (Veeco Dektak 3ST) (contact pressure 4 mg, measurement speed 2 mm/30 s). The profile of a layer edge which forms at the boundary between a coated region and an uncoated region on the glass substrate (owing to the use of a shadow mask) is determined here. The layer thickness of the test layer can be determined from the difference in height between the two regions. The accuracy of the layer thicknesses using this method is about +/−5%.

General Determination of the HOMO, LUMO and Energy Gap from Cyclic Voltammetry and Absorption Spectrum

For the purposes of the present invention, the HOMO and LUMO values and the energy gap are determined by the general methods described below:

The HOMO value arises from the oxidation potential, which is measured by cyclic voltammetry (CV) at room temperature. The measuring instrument used for this purpose is an ECO Autolab system with Metrohm 663 VA stand. The working electrode is a gold electrode, the reference electrode is Ag/AgCl, the bridge electrolyte is KCl (3 mol/l) and the auxiliary electrode is platinum.

For the measurement, firstly a 0.11 M conductive-salt solution of tetrabutylammonium hexafluorophosphate (NH₄PF₆) in dichloromethane is prepared, introduced into the measurement cell and degassed for 5 min. Two measurement cycles are subsequently carried out with the following parameters:

Measurement technique: CV
Initial purge time: 300 s
Cleaning potential: −1 V
Cleaning time: 10 s
Deposition potential: −0.2 V
Deposition time: 10 s
Start potential: −0.2 V
End potential: 1.6 V
Voltage step: 6 mV
Sweep rate: 50 mV/s

1 ml of the sample solution (10 mg of the substance to be measured in 1 ml of dichloromethane) is subsequently added to the conductive-salt solution, and the mixture is degassed again for 5 min. Five further measurement cycles are subsequently carried out, the last three of which are recorded for evaluation. The same parameters are set as described above.

0.1 ml of ferrocene solution (100 mg of ferrocene in 1 ml of dichloromethane) is subsequently added to the solution, the mixture is degassed for 1 min, and a measurement cycle is carried out with the following parameters:

Measurement technique: CV
Initial purge time: 60 s
Cleaning potential: −1 V
Cleaning time: 10 s
Deposition potential: −0.2 V
Deposition time: 10 s
Start potential: −0.2 V
End potential: 1.6 V
Voltage step: 6 mV
Sweep rate: 50 mV/s

For evaluation, the mean of the voltages of the first oxidation maximum is taken from the forward curves and the mean of the voltages of the associated reduction maximum is taken from the return curves (V_{P} and V_{F}) for the sample solution and the solution to which ferrocene solution has been added, where the voltage used is in each case the voltage against ferrocene. The HOMO value of the substance to be investigated E_{HOMO} arises as E_{HOMO}=−[e·(V_{P}−V_{F})+4.8 eV], where e represents the elementary charge.

It should be noted that appropriate modifications of the measurement method may have to be carried out in individual cases, for example if the substance to be investigated is not soluble in dichloromethane or if decomposition of the substance occurs during the measurement. If a meaningful measurement should not be possible by means of CV using the above-mentioned method, the HOMO energy will be determined by photoelectron spectroscopy by means of a model AC-2 photoelectron spectrometer from Riken Keiki Co. Ltd. (http://www.rikenkeiki.com/pages/AC2.htm), in which case it should be noted that the values obtained are typically around 0.3 eV more negative than those measured using CV. For the purposes of this patent, the HOMO value is then taken to mean the value from Riken AC-2+0.3 eV. Thus, if a value of −5.6 eV is measured with, for example, Riken AC-2, this corresponds to a value of −5.3 eV measured using CV.

Furthermore, HOMO values lower than −6 eV cannot be measured reliably either using the CV method described or using the photoelectron spectroscopy described. In this case, the HOMO values are determined from quantum-chemical calculation by means of density functional theory (DFT). This is carried out via the commercially available Gaussian 03W (Gaussian Inc.) software using method B3PW91/6-31G(d). Standardisation of the calculated values to CV values is achieved by comparison with materials which can be measured from CV. To this end, the HOMO values for a series of materials are measured using the CV method and also calculated. The calculated values are then calibrated by means of the measured values, and this calibration factor is used for all further calculations. In this way, it is possible to calculate HOMO values which correspond very well to those which would be measured by CV. If the HOMO value for a particular substance cannot be measured by CV or Riken AC-2 as described above, the HOMO value is, for the purposes of this patent, therefore taken to mean the value which is obtained in accordance with the description by a DFT calculation calibrated to CV, as described above. Examples of values calculated in this way for some common organic materials are: NPB (HOMO −5.16 eV, LUMO −2.28 eV); TCTA (HOMO −5.33 eV, LUMO −2.20 eV); TPBI (HOMO −6.26 eV, LUMO −2.48 eV). These values can be used for calibration of the calculation method.

The energy gap is determined from the absorption edge of the absorption spectrum measured on a film having a layer thickness of 50 nm. The absorption edge here is defined as the wavelength obtained when a straight line is fitted to the longest-wavelength falling flank in the absorption spectrum at its steepest point, and the value at which this straight line intersects the wavelength axis, i.e. the absorption value=0, is determined.

The LUMO value is obtained by addition of the energy gap to the HOMO value described above.

### General Production of OLEDs, Description of the Examples

OLEDs according to the invention and OLEDs in accordance with the prior art are produced by a general process in accordance with WO 04/058911, which is adapted to the circumstances described here (layer-thickness variation, materials used).

The results for various OLEDs are presented in Examples 1 to 14 below (see Tables 1 and 4). Glass plates which have been coated with structured ITO (indium tin oxide) in a thickness of 150 nm are coated with 20 nm of PEDOT (poly(3,4-ethylenedioxy-2,5-thiophene), spin-coated from water; purchased from H.C. Starck, Goslar, Germany) for improved processing. These coated glass plates form the substrates, to which the OLEDs are applied. The OLEDs basically have the following layer structure: substrate/optional hole-injection layer (HIL)/hole-transport layer (HTL)/optional interlayer (IL)/electron-blocking layer (EBL)/emission layer (EML)/optional hole-blocking layer (HBL)/electron-transport layer (ETL) according to the invention/optional second electron-transport layer (ETL2)/optional electron-injection layer (EIL) and finally a cathode. The cathode is formed by an aluminium layer with a thickness of 100 nm. The precise layer structure of the OLEDs is shown in Table 1. The materials used for the production of the OLEDs are shown in Table 3. Table 2 contains the electron mobility of the electron-transport materials used in an electric field of 10⁵V/cm (for determination of the mobility see Example 1). In the case of the use of materials TPBI, Alq₃, ETM1 and ETM2 in the electron-transport layer, OLEDs in accordance with the prior art are obtained, whereas in the case of the use of ETM3 to ETM6 in thick layers, components according to the invention are obtained.

The performance data of the OLEDs are summarised in Table 4. The examples are divided into “a” and “b” for better clarity, where all examples ending in “a” contain thin electron-transport layers and all examples ending in “b” contain thick electron-transport layers. In accordance with the electron mobilities of the materials used, Examples 1-7 (both “a” and “b”) are OLEDs in accordance with the prior art. The same applies to Examples 8-14 ending in “a”, which contain thin electron-transport layers and serve as comparison with the OLEDs according to the invention. The OLEDs according to the invention are Examples 8-14 ending in “b”, since materials having a correspondingly high electron mobility in correspondingly thick electron-transport layers are employed here.

The electron-transport layer thickness is optimised in all OLEDs in order to obtain good performance data. This applies both to the OLEDs comprising a thin electron-transport layer and to those comprising a thick electron-transport layer. Components which have been optimised with respect to the ETL thickness are thus compared below.

All materials are applied by thermal vapour deposition in a vacuum chamber. The emission layer here always consists of at least one matrix material (host material) and an emitting dopant (emitter), which is admixed with the matrix material or materials in a certain proportion by volume by coevaporation. Information such as H3:CBP:TER1 (55%:35%:10%) here means that material H3 is present in the layer in a proportion by volume of 55%, CBP is present in a proportion of 35% and TER1 is present in a proportion of 10%. Analogously, the electron-transport layer may also consist of a mixture of two materials.

The OLEDs are characterised by standard methods. For this purpose, the electroluminescence spectra, the current efficiency (measured in cd/A) and the power efficiency (measured in Im/W) as a function of the luminous density, calculated from current-voltage-luminance characteristic lines (IUL characteristic lines), and the lifetime are determined. The lifetime is defined as the time after which the luminous density has dropped to a certain proportion from a certain initial luminous density. LD80 means that the said lifetime is the time at which the luminous density has dropped to 80% of the initial luminous density, i.e. from, for example, 4000 cd/m² to 3200 cd/m². Analogously, LD50 would be the time after which the initial luminous density has dropped to half. The values for the lifetime can be converted to data for other initial luminous densities with the aid of conversion formulae known to the person skilled in the art.

### Determination of the Proportion of Short Circuits

In order to comment on the improvement to be expected in the production yield in mass production, the proportion of OLEDs that form a short circuit within a certain operating period is determined. Such OLEDs do not emit light, are therefore classified as rejects for the purposes of mass production and thus reduce the production yield.

In each case, 32 OLEDs having an identical layer structure are produced. Their lifetime is determined as described above. During the lifetime measurement, the proportion of the OLEDs that have a short circuit after an operating time of 100 h is determined. A short circuit can be recognised from the luminance suddenly dropping to a very low value or zero. Table 4 shows how many of the 32 OLEDs have such a short circuit. A value of 0/32 means that all OLEDs still function after 100 h.

### Blue-Emitting Fluorescent OLEDs

On use of a thick ETL, the colour coordinates for blue emission improve, and the number of short circuits is likewise significantly reduced (comparison of Example 6a with 6b and 12a with 12b). If Alq₃ (prior art) is used in combination with a blue-fluorescent emission layer, the voltage increases very clearly from 6.4 V to 13.3 V on use of a thick ETL (Examples 6a and 6b). Although the current efficiency (in cd/A) increases slightly, this has the consequence that the power efficiency is approximately halved from 2.5 to 1.3 Im/W. Owing to the high operating voltage, the energy input into the component increases significantly, causing the lifetime to deteriorate significantly compared with the thin ETL (from 160 h to 95 h).

In the case of a component according to the invention, the situation is different: if a thick layer of material ETM3 is used, only a moderate increase in the operating voltage is obtained, which, in combination with the slight increase in the current efficiency, results in a power efficiency and lifetime which are similar compared with the thin ETL (Examples 12a and 12b). The advantage of the ETL according to the invention is thus an improved colour coordinate and a smaller number of short circuits with comparable power efficiency and lifetime.

### Red-Emitting Phosphorescent OLEDs

In the case of red emission, a similar case exists as for the blue emission just described. Here too, the OLEDs according to the invention are distinguished by the fact that they give improved colour coordinates and a reduced number of short circuits, with the power efficiency and lifetime at the same level as in the case of thin electron-transport layers (Examples 7a, 7b and 13a and 13b, where 13b is the OLED according to the invention).

### Green-Emitting Phosphorescent OLEDs

The greatest advantage arises on use of electron-transport layers according to the invention in OLEDs which exhibit green phosphorescence. This is due to the fact that the emission spectrum becomes narrower on use of correspondingly thick emission layers. In the case of blue and red emission, this only results in slight improvements in the colour coordinates, but this effect is more pronounced in the green spectral region. Furthermore, a more significant increase in the current efficiency can be achieved in the case of green emission, which has the consequence that even better power efficiencies can be achieved with electron-transport layers according to the invention than with thin ETLs, in spite of somewhat higher operating voltages. Particular mention should be made here of Examples 11a and 11b, which show a significant increase of 10% in the power efficiency on use of an ETL according to the invention. In the same example, a slight increase in the lifetime is also observed, which is due, in particular, to the better current efficiency of the OLED comprising an ETL according to the invention.

In addition, the proportion of short circuits can be significantly reduced with a thick electron-transport layer in the case of green emission. Besides the advantages mentioned for blue and red, an increase in the power efficiency and a moderate improvement in the lifetime are also possible for green emission in the case of the use of an electron-transport layer according to the invention.

TABLE 1
Structure of the OLEDs

| | HIL | HTL | IL | EBL | EML | HBL | ETL | ETL2 | EIL2 |
|---|---|---|---|---|---|---|---|---|---|
| Ex. | thickness | thickness | thickness | thickness | thickness | thickness | thickness | thickness | thickness |
| 1a | — | HTM1 | HIL1 | EBM1 | H3:TEG1 | — | TPBI | — | LiF |
| | | 70 nm | 5 nm | 130 nm | (85%:15%) | | 40 nm | | 1 nm |
| | | | | | 30 nm | | | | |
| 1b | — | ″ | ″ | ″ | ″ | — | TPBI | — | ″ |
| | | | | | | | 180 nm | | |
| 2a | — | ″ | ″ | ″ | ″ | — | Alq3 | — | ″ |
| | | | | | | | 40 nm | | |
| 2b | — | ″ | ″ | ″ | ″ | — | Alq3 | — | ″ |
| | | | | | | | 180 nm | | |
| 3a | — | ″ | ″ | ″ | ″ | — | ETM1 | — | ″ |
| | | | | | | | 40 nm | | |
| 3b | — | ″ | ″ | ″ | ″ | — | ETM1 | — | ″ |
| | | | | | | | 180 nm | | |
| 4a | — | ″ | ″ | ″ | ″ | — | ETM2 | — | LiQ |
| | | | | | | | 40 nm | | 2 nm |
| 4b | — | ″ | ″ | ″ | ″ | — | ETM2 | — | LiQ |
| | | | | | | | 180 nm | | 2 nm |
| 5a | — | HTM1 | HIL1 | EBM1 | H2:TEG1 | — | Alq3 | — | LiF |
| | | 70 nm | 5 nm | 65 nm | (85%:15%) | | 40 nm | | 1 nm |
| | | | | | 30 nm | | | | |
| 5b | — | ″ | ″ | ″ | ″ | — | Alq3 | — | ″ |
| | | | | | | | 180 nm | | |
| 6a | HIL1 | HTM1 | — | NPB | H1:D1 (95%:5%) | — | Alq3 | — | ″ |
| | 5 nm | 140 nm | | 20 nm | 30 nm | | 20 nm | | |
| 6b | ″ | ″ | — | ″ | ″ | — | Alq3 | — | ″ |
| | | | | | | | 145 nm | | |
| 7a | — | HTM1 | — | NPB | ETM3:CBP:TER1 | ETM3 | Alq3 | — | ″ |
| | | 20 nm | | 20 nm | (45%:45%:10%) | 10 nm | 20 nm | | |
| | | | | | 30 nm | | | | |
| 7b | ″ | ″ | — | ″ | ″ | ″ | Alq₃ | — | ″ |
| | | | | | | | 240 nm | | |
| 8a | — | HTM1 | HIL1 | EBM1 | H3:TEG1 | — | ETM3 | — | LiQ |
| | | 70 nm | 5 nm | 130 nm | (85%:15%) | | 40 nm | | 3 nm |
| | | | | | 30 nm | | | | |
| 8b | — | ″ | ″ | ″ | ″ | — | ETM3 | — | ″ |
| | | | | | | | 180 nm | | |
| 9a | — | ″ | ″ | ″ | ″ | ETM3:LiQ | ETM3 | — | ″ |
| | | | | | | (50%:50%) | 30 nm | | |
| | | | | | | 10 nm | | | |
| 9b | — | ″ | ″ | ″ | ″ | ″ | ETM3 | — | ″ |
| | | | | | | | 170 nm | | |
| 10a | — | ″ | ″ | EBM1 | H2:TEG1 | — | ETM4 | — | ″ |
| | | | | 65 nm | (85%:15%) | | 40 nm | | |
| | | | | | 30 nm | | | | |
| 10b | — | ″ | ″ | ″ | ″ | — | ETM4 | — | ″ |
| | | | | | | | 180 nm | | |
| 11a | — | ″ | ″ | EBM1 | H3:TEG1 | — | ETM6 | — | LiF |
| | | | | 130 nm | (85%:15%) | | 40 nm | | 1.5 nm |
| | | | | | 30 nm | | | | |
| 11b | — | ″ | ″ | ″ | ″ | — | ETM6 | — | LiF |
| | | | | | | | 180 nm | | 1.5 nm |
| 12a | HIL1 | HTM1 | — | NPB | H1:D1 (95%:5%) | — | ETM3 | — | LiQ |
| | 5 nm | 140 nm | | 20 nm | 30 nm | | 20 nm | | 3 nm |
| 12b | ″ | ″ | — | ″ | ″ | — | ETM3 | — | ″ |
| | | | | | | | 145 nm | | |
| 13a | — | HTM1 | — | NPB | ETM3:CBP:TER1 | ETM4 | ETM4 | — | LiQ |
| | | 20 nm | | 20 nm | (45%:45%:10%) | 10 nm | 30 nm | | 2.5 nm |
| | | | | | 30 nm | | | | |
| 13b | ″ | ″ | — | ″ | ″ | ″ | ETM4 | — | LiQ |
| | | | | | | | 240 nm | | 2.5 nm |
| 14a | — | HTM1 | HIL1 | EBM1 | H3:TEG1 | — | ETM5 | ETM3:LiQ | — |
| | | 70 nm | 5 nm | 130 nm | (85%:15%) | | 35 nm | (20%:80%) | |
| | | | | | 30 nm | | | 5 nm | |
| 14b | ″ | ″ | — | ″ | ″ | ″ | ETM5 | ″ | — |
| | | | | | | | 175 nm | | |

TABLE 2
Electron mobility of the electron-
transport materials used

| Material | μₑ at E = 10⁵ V/cm | |
|---|---|---|
| TPBI | 9.3 · 10⁻⁸ | cm²/(Vs) |
| Alq₃ | 2.1 · 10⁻⁶ | cm²/(Vs) |
| ETM1 | 5.7 · 10⁻⁶ | cm²/(Vs) |
| ETM2 | 8.2 · 10⁻⁶ | cm²/(Vs) |
| ETM3 | 1.5 · 10⁻⁴ | cm²/(Vs) |
| ETM4 | 1.4 · 10⁻⁴ | cm²/(Vs) |
| ETM5 | 2 · 10⁻⁴ | cm²/(Vs) |
| ETM6 | 7 · 10⁻⁴ | cm²/(Vs) |

TABLE 3
Structural formulae of the materials used

```
  TPBI
  Alq₃
```

```
  ETM1
  ETM2
  ETM3
```

ETM4

```
  ETM5
  ETM6
  HIL1
  HTM1
  EBM1
  NPB
  H1
  D1
  H2
  H3
  TEG
  TER
```

TABLE 4
Performance data of the various OLEDs

| | Voltage for | Efficiency at | Efficiency at | CIE x/y at | LD80 from | Proportion of |
|---|---|---|---|---|---|---|
| Ex. | 1000 cd/m2 | 1000 cd/m2 | 1000 cd/m² | 1000 cd/m² | 4000 cd/m² | short circuits |
| 1a | 4.1 V | 47 cd/A | 36.0 lm/W | 0.372/0.594 | 370 h | 3/32 |
| 1b | 20.2 V | 45 cd/A | 7.0 lm/W | 0.338/0.618 | 115 h | 1/32 |
| 2a | 3.9 V | 44 cd/A | 35.4 lm/W | 0.357/0.606 | 620 h | 2/32 |
| 2b | 7.9 V | 48 cd/A | 19.1 lm/W | 0.337/0.621 | 375 h | 0/32 |
| 3a | 4.3 V | 43 cd/A | 31.4 lm/W | 0.361/0.606 | 410 h | 2/32 |
| 3b | 6.5 V | 46 cd/A | 22.2 lm/W | 0.341/0.618 | 310 h | 0/32 |
| 4a | 3.9 V | 44 cd/A | 35.4 lm/W | 0.366/0.603 | 330 h | 5/32 |
| 4b | 5.9 V | 53 cd/A | 28.2 lm/W | 0.338/0.618 | 270 h | 2/32 |
| 5a | 3.9 V | 47 cd/A | 37.8 lm/W | 0.351/0.611 | 600 h | 3/32 |
| 5b | 7.7 V | 51 cd/A | 20.7 lm/W | 0.321/0.637 | 330 h | 1/32 |
| 7a | 4.8 V | 9.8 cd/A | 6.5 lm/W | 0.676/0.323 | 340 h | 7/32 |
| 7b | 17.3 V | 10.9 cd/A | 2.0 lm/W | 0.692/0.310 | 190 h | 2/32 |
| 8a | 2.9 V | 55 cd/A | 60 lm/W | 0.364/0.602 | 480 h | 2/32 |
| 8b | 3.3 V | 67 cd/A | 63 lm/W | 0.342/0.622 | 520 h | 0/32 |
| 9a | 3.3 V | 52 cd/A | 50 lm/W | 0.367/0.599 | 530 h | 3/32 |
| 9b | 4.1 V | 63 cd/A | 48 lm/W | 0.355/0.620 | 550 h | 1/32 |
| 10a | 3.0 V | 57 cd/A | 60 lm/W | 0.350/0.613 | 460 h | 3/32 |
| 10b | 3.3 V | 66 cd/A | 62 lm/W | 0.312/0.642 | 510 h | 0/32 |
| 11 a | 2.8 V | 53 cd/A | 59 lm/W | 0.379/0.588 | 290 h | 5/32 |
| 11 b | 3.0 V | 62 cd/A | 65 lm/W | 0.37/0.612 | 330 h | 2/32 |
| 13a | 4.1 V | 10.3 cd/A | 7.8 lm/W | 0.679/0.321 | 310 h | 9/32 |
| 13b | 5.5 V | 13.8 cd/A | 7.9 lm/W | 0.687/0.312 | 320 h | 3/32 |
| 14a | 3.4 V | 55 cd/A | 52 lm/W | 0.36/0.604 | 510 h | 3/32 |
| 14b | 4.0 V | 68 cd/A | 53 lm/W | 0.304/0.624 | 500 h | 0/32 |
| | Voltage for | Efficiency at | Efficiency at | CIE x/y at | LD50 from | Proportion of |
| | 1000 cd/m2 | 1000 cd/m2 | 1000 cd/m² | 1000 cd/m² | 6000 cd/m² | short circuits |
| 6a | 6.4 V | 5.1 cd/A | 2.5 lm/W | 0.142/0.152 | 160 h | 3/32 |
| 6b | 13.3 V | 5.6 cd/A | 1.3 lm/W | 0.144/0.140 | 95 h | 0/32 |
| 12a | 14.3 V | 8.2 cd/A | 6.0 lm/W | 0.141/0.147 | 145 h | 3/32 |
| 12b | 5.1 V | 9.4 cd/A | 5.8 lm/W | 0.139/0.135 | 140 h | 1/32 |

1-15. (canceled)

16. An organic electroluminescent device comprising an anode, a cathode and at least one emitting layer, wherein an electron-transport layer which has a layer thickness of at least 80 nm and which has an electron mobility of at least 10⁻⁵ cm²/Vs in a field of 10⁵ V/cm is arranged between the emitting layer and the cathode.

17. The organic electroluminescent device according to claim 16, wherein the layer thickness of the electron-transport layer is at least 100 nm.

18. The organic electroluminescent device according to claim 16, wherein the layer thickness of the electron-transport layer is not thicker than 500 nm.

19. The organic electroluminescent device according to claim 16, wherein the layer thickness of the electron-transport layer is at least 130 nm a the layer thickness of the electron-transport layer is not thicker than 350 nm.

20. The organic electroluminescent device according to claim 16, wherein the electron mobility of the electron-transport layer is at least 5×10⁻⁵ cm²/Vs in a field of 10⁵ V/cm.

21. The organic electroluminescent device according to claim 19, wherein the electron mobility of the electron-transport layer is at least 10⁻⁴ cm²/Vs in a field of 10⁵ V/cm.

22. The organic electroluminescent device according to claim 16, wherein the electron-transport layer consists of a pure material or of a mixture of two or more materials.

23. The organic electroluminescent device according to claim 16, wherein the electron-transport layer has only one layer or in that it is composed of a plurality of individual electron-transport layers whose total thickness is at least 80 nm and of which each individual layer has an electron mobility of at least 10⁻⁵ cm²/Vs in a field of 10⁵ V/cm.

24. The organic electroluminescent device according to claim 16, wherein only materials which have an HOMO of <−4 eV, are used in the electron-transport layer.

25. The organic electroluminescent device according to claim 16, wherein only materials which have an LUMO of >−3.5 eV, are used in the electron-transport layer.

26. The organic electroluminescent device according to claim 16, wherein only materials which have an HOMO of <−5 eV, are used in the electron-transport layer and only materials which have an LUMO of >−3 eV, are used in the electron-transport layer.

27. The organic electroluminescent device according to claim 16, wherein the electron-transport materials for the electron-transport layer are selected from the structure classes of the triazine derivatives, the benzimidazole derivatives, the pyrimidine derivatives, the pyrazine derivatives, the pyridazine derivatives, the oxazole derivatives, the oxadiazole derivatives, the phenanthroline derivatives, the thiazole derivatives, the triazole derivatives or the aluminium, lithium or zirconium complexes.

28. The organic electroluminescent device according to claim 16, wherein the electron-transport materials are employed in combination with an organic alkali-metal compound in the electron-transport layer.

29. The organic electroluminescent device according to claim 16, wherein it has a fluorescent or phosphorescent emitting layer.

30. The organic electroluminescent device according to claim 16, wherein it has a fluorescent or phosphorescent emitting layer, where the fluorescent layer is blue- or green-fluorescent and the phosphorescent layer is green- or red-phosphorescent.

31. The organic electroluminescent device according to claim 16, wherein the emitting compound, if it is a phosphorescent compound, is a compound which contains copper, molybdenum, tungsten, rhenium, ruthenium, osmium, rhodium, iridium, palladium, platinum, silver, gold or europium, where this compound is employed in combination with a matrix material, selected from the group consisting of ketones, phosphine oxides, sulfoxides, sulfones, triarylamines, carbazole derivatives, indolocarbazole derivatives, indenocarbazole derivatives, azacarbazole derivatives, bridged carbazole derivatives, bipolar matrix materials, silanes, azaboroles, boronic esters, triazine derivatives, zinc complexes, diaza- or tetraazasilole derivatives and diazaphosphole derivatives;
or in that the emitting compound, if it is a fluorescent compound, is selected from the class of the monostyrylamines, the distyrylamines, the tristyrylamines, the tetrastyrylamines, the styrylphosphines, the styryl ethers, the arylamines or the condensed aromatic hydrocarbons, where these compounds are each employed in combination with a matrix material, selected from the group consisting of oligoarylenes, preferably oligoarylenes containing condensed aromatic groups, in particular containing anthracene, naphthalene, benzanthracene, benzophenanthrene and mixtures thereof.

32. The organic electroluminescent device according to claim 16, wherein the emitting layer is a green-emitting layer.

33. The organic electroluminescent device according to claim 16, wherein the electroluminescent device, in the case of the use of a phosphorescent emission layer, comprises a hole-blocking layer between the emission layer and the electron-transport layer.

34. A process for the production of the organic electroluminescent device according to claim 16, which comprises applying one or more layers by means of a sublimation process or in that one or more layers are applied by means of the OVPD (organic vapour phase deposition) process or with the aid of carrier-gas sublimation or in that one or more layers are applied from solution.

35. A process for the production of the organic electroluminescent device according to claim 16, which comprises applying one or more layers by means of a sublimation process or in that one or more layers are applied by means of the OVPD (organic vapour phase deposition) process or with the aid of carrier-gas sublimation or in that one or more layers are applied from solution, by spin coating, or by means of printing process.
